(19) United States
(12) Patent Application Publication
(10) Pub. No.: US 2015/0070984 A1
(43) Pub. Date: Mar. 12, 2015

(54) SPIN VALVE

(71) Applicant: HELMHOLTZ-ZENTRUM BERLIN FUER MATERIALIEN UND ENERGIE GMBH, Berlin (DE)

(72) Inventor: Florin Radu, Berlin (DE)

(21) Appl. No.: 14/383,131

(22) PCT Filed: Mar. 1, 2013
(86) PCT No.: PCT/DE2013/000132

§ 371 Date: Sep. 5, 2014

(30) Foreign Application Priority Data
Mar. 5, 2012 (DE) 10 2012 005 134.4

(51) Int. Cl. H01L 43/02; G11C 11/16; H01L 43/10

(52) U.S. Cl. CPC H01L 43/02; H01L 43/10; G11C 11/161; G11C 11/1675
USPC 365/158; 257/421

(57) ABSTRACT

A spin valve includes two layers, a reference layer and a free layer, magnetised perpendicularly to a layer plane and an intermediate layer disposed between the magnetic layers. The reference layer predetermines a preferred orientation of a direction of the magnetisation, is formed from a ferrimagnetic material, and has a higher coercive field strength than the free layer. The free layer is formed from a ferromagnetic or ferrimagnetic material. The intermediate layer is electrically conductive or non-conductive. The reference layer and the free layer have a single-domain magnetisation. The reference layer is formed from an alloy comprising a rare earth element and a transition metal. The coercive field strength of the reference layer is set via its composition and is more than 0.8 kA/m. An anisotropy and layer thickness of the reference layer and a coupling constant define an exchange bias field between 0.8 and 80 kA/m.

### CROSS-REFERENCE TO RELATED APPLICATIONS

This application is a U.S. National Phase application under 35 U.S.C. §371 of International Application No. PCT/DE2013/000132, filed on Mar. 1, 2013, and claims benefit to German Patent Application No. DE 10 2012 005 134.4 A1, filed on Mar. 5, 2012. The International Application was published in German on Sep. 12, 2013, as WO 2013/131510 A1 under PCT Article 21 (2).

### FIELD

The invention relates to a spin valve, having a perpendicularly magnetised ferrimagnetic reference layer and a perpendicularly magnetised ferri- or ferromagnetic free layer, which are separated by an intermediate layer.

### BACKGROUND

In digital storage technology, two groups of memories are distinguished with regards to the durability of the stored information thereof.

One group comprises memories with what is known as volatile behaviour, into which fall memories with read and write access, which are termed RAM (Random Access Memory) in accordance with ISO 2382-12 [0]. The literal meaning of random access memory (direct-access memory) also applying by contrast for non-volatile memories and to some extent also being used as such.

The storage behaviour of volatile memories is characterised in that the stored data is lost if the energy supply is lost.

RAMs are generally semiconductor memories, which store stored information in the form of space charges in transistor units.

What are known as dynamic RAMs (DRAM) are distinguished by rapid storage and deleting behaviour. Owing to the volatility, stored data must be refreshed more often (many times in a second), however.

What are known as static RAMs (SRAM) do not require refreshing like DRAMs, but likewise lose the memory contents thereof if the energy supply is lost (volatile behaviour). The construction thereof is complex, for which reason, SRAMs are only used for small memory units.

The other group comprises memories with what is known as non-volatile behaviour, into which fall memories with only read access (ROMs, read-only memories) and mechanically addressed storage media, such as e.g. magnetic tapes, hard disks and optical discs.

ROMs are complicated to produce, but can be read quickly, whereas the mechanically addressed memories are simple to produce, but slow.

Magnetoresistive RAMs (MRAMs) are assuming an important position with much development potential. Contrary to the RAM portion of the name thereof, these are non-volatile storage elements, which bear the name RAM as they are a direct-access memory unit (see above).

In the simplest case, these are formed from what are known as spin valves, a spin valve forming one bit in an MRAM memory unit.

Spin valves are in turn arrangements of at least two layers, which have a magnetic orientation and which are for the most part of ferromagnetic nature, arrangements with ferrimagnetic layers also being known and one of the layers being used as a reference layer for the magnetic preferred orientation direction of the layer structure.

The magnetisation of the reference layer is for the most part set by a combination of an antiferromagnetic with a ferromagnetic layer. Between the antiferromagnetic layer and the ferromagnetic layer, there is a direct exchange interaction, which leads to an exchange bias (exchange anisotropy, also unidirectional anisotropy), which effects a preferred orientation of the magnetisation of the ferromagnetic layer.

An exchange interaction may be present in the case of a direct contact of the materials and indirectly in the case of a separation, for example due to an intermediate layer, of the materials. The exchange bias is a special case of exchange interaction, in which a preferred orientation of the magnetisation is transferred.

For preferred orientation of the magnetisation, the exchange bias is additionally characterised by the shifting of the magnetic hysteresis curves by the value HEB, what is known as the exchange bias field. The hysteresis curves then no longer run symmetrically with the applied external field owing to the preferred orientation that is set. An increase in the coercive field strength HC, i.e. the field strength at which the magnetisation of the material is reset to zero, often accompanies the exchange bias.

The orientation of the magnetisation in the case of an exchange bias can lie in the layer plane or perpendicular to the same or be tilted with respect to the same.

Magnetic moments present perpendicularly to the layer planes have the advantage of stabilising the exchange bias and the magnetic properties of the spin valve. By contrast, in most known arrangements, the alignment of the magnetic orientation lies parallel to the layer planes.

In the case of the conventionally used combinations of ferromagnetic and antiferromagnetic materials, what is known as a field cooling procedure is needed for setting the exchange anisotropy. Here, the materials are heated above what is known as the Néel temperature, that is the temperature at which an antiferromagnet becomes paramagnetic, and cooled in a magnetic field, which leads to the alignment of the magnetic orientation in the antiferromagnetic material and thus to the formation of the exchange bias between the layers.

What is known as the field growing procedure, in which the alignment of the orientation of the magnetisation takes place via a very large external magnetic field, constitutes an alternative to the field cooling procedure.

The field cooling and field growing procedures are energy intensive due to the required, possibly very high fields and, in the case of the field cooling procedure, additionally require the heating of the layers. A further heating of these layers during operation is undesirable, as this leads to instabilities.

By using ferrimagnetic materials for the reference layers, both a field cooling procedure or a field growing procedure and the additional antiferromagnetic layer become superfluous.

For a system made from ferromagnetic cobalt nanoparticles—embedded in graphite, aluminium oxide or antiferromagnetic cobalt oxide—it was possible to show that an exchange bias has a stabilising effect on the maintenance of the preferred orientation, as is presented in the article from Skumryev et al. “Beating the superparamagnetic limit with Exchange Bias” (Nature, Vol. 423, Issue (19), 850ff).

In addition, the reference layer, which—as already mentioned—is built up from a combination of ferromagnetic and antiferromagnetic layers with exchange bias, is temporally unstable with respect to the orientated magnetisation. As a result, memory units are lost over time in MRAMs, which entails a disadvantage of the same, as a reset or rewriting of the units cannot be carried out because of the usually very high coercive field strengths of several thousand kA/m (several tens to hundreds kOe).

A further property of layer systems made up of two magnetic layers having an exchange bias is what is known as the training effect. Here, the exchange bias field HEB and the coercive field strength HC can be reduced primarily in the case of the first reversal of the magnetisation of the ferromagnetic layer. Among other things, change of the magnetic domains in the materials is blamed as a cause for this. A magnetic domain is a spatial unit, in which a unified magnetisation is present. A material with a completely unified magnetisation is single domain.

The reference layer in a spin valve has a higher coercive field strength than the other, so-called free layer.

Depending on whether the directions of the magnetic orientation are formed parallel or anti-parallel in the layers, reference layer and free layer, the conductance or the resistance is changed by the intermediate layer of the spin valve arranged between these layers. This can lead inter alia to arrangements with a giant magneto resistance (GMR) of the spin valve. As the resistance changes with the magnetisation, the units here termed spin valves are also termed magnetoresistive elements, which is also eponymous for the term MRAM.

The magnetic field sensor with ferromagnetic thin layer developed by P. Grünberg is described in DE 38 20 475 C1, which is today termed a spin valve or magnetoresistive element.

The state of the spin valve, the parallel or anti-parallel aligned magnetisation thereof, also influences a possible tunnel current perpendicular to the layer planes, if an insulating intermediate layer of suitable thickness is arranged between the same. In the case of an element, which operates with the change of the tunnel current, on speaks of a tunnel magnetoresistive (TMR) element.

Reading out the state of a spin valve takes place in the simplest case by measuring the resistance (absolute value detection method). The information is then stored in the free layer. The magnetisation of the layers, reference layer and free layer is not coupled in this case, that is to say there is no exchange anisotropy between the reference layer and the free layer. This is the customary read-out mechanism and also the exchange interaction that is usually set.

Storing usually takes place by means of a magnetic field which is very large locally or a high current flow at values sufficient for commutating the direction of the magnetisation of the free layer. The energies required for the storage process are therefore relatively large compared to other storage media—which are known according to the prior art—which constitutes a disadvantage of MRAMs. They depend on the size of the coercive field strength of the relevant layer, which are likely to have to be at least a few kA/m to several tens of kA/m (a few hundred to thousand Oe) for switching over the free layer.

An MRAM is formed by means of an array of spin valves. For storage, in the simplest case, a locally high field is generated by a current flow through a line located above a spin valve and through a line located below the spin valve, which is arranged perpendicularly to the upper line. The read process takes place in the simplest case of the direct value detection method by means of the measurement of the resistance. In the case of TMR elements, a measured current flow, which flows through two contacts on the spin valve, upper and lower, perpendicularly to the layers, is used. The array made up of spin valves is correspondingly contacted for fulfilling the read and write procedures.

The prior art from which the invention proceeds is described in EP 1 244 118 B1. The spin valve described there has two layers magnetised perpendicularly to the layer plane, which can be formed from ferrimagnetic materials and which are separated by an insulating intermediate layer. In this case, the one layer with the higher coercive field strength is used as reference layer. The arrangement is termed a magnetoresistive element here and is optimised for use as a TMR element. The reference layer and the free layer are decoupled to the greatest extent possible. The condition M·250·h/(π·(L+2.6))<Hs is specified for the decoupling of the layers, where M is the residual magnetisation, L is the length and h is the layer thickness of the reference layer and Hs represents the saturation magnetic field of the free layer. Under these conditions, no exchange bias can be set. A stabilisation of the preferred orientation of the free layer by means of the exchange bias therefore remains excluded.

### SUMMARY

In an embodiment, the present invention provides a spin valve comprising two layers, a reference layer and a free layer, magnetised perpendicularly to a layer plane and an intermediate layer disposed between the magnetic layers. The reference layer predetermines a preferred orientation of a direction of the magnetisation, is formed from a ferrimagnetic material, and has a higher coercive field strength than the free layer. The free layer is formed from a ferromagnetic or ferrimagnetic material. The intermediate layer is electrically conductive or non-conductive. The reference layer and the free layer have a single-domain magnetisation. The reference layer is formed from an alloy comprising a rare earth element and a transition metal. The coercive field strength of the reference layer is set settable via the composition thereof and is more than 0.8 kA/m. An anisotropy (KRS) and layer thickness (dRS) of the reference layer and a coupling constant (J), which is a function of a layer thickness (dZS) of the intermediate layer

fulfill a condition for forming an exchange bias with (KRS·dRS)/J(dZS)>1, and the exchange bias field has values between 0.8 and 80 kA/m.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 shows the schematic arrangement of the layers in the spin valve (prior art),

FIG. 2 shows hystereses of the magnetisation of Dy and Gd, measured by means of x-ray magnetic circular dichroism,

FIG. 3 shows hystereses of the magnetisation of Fe after saturation of the magnetic moments in an external field, measured by means of x-ray magnetic circular dichroism,

FIG. 4 shows sizes of Hc and HEB after switching over the orientation of the magnetisation of the free layer by means of an external field one to three times.

### DETAILED DESCRIPTION

An aspect of the present invention provides a spin valve, which allows a resetting of the magnetic orientation of the reference layer (reset) and the free layer in a low-energy manner, without a field cooling or field growing procedure becoming necessary. In addition, the spin valve should have a controlled temporal stability of stored information of a few days to years and not have a training effect.

In an embodiment, a direct exchange interaction between two layers magnetised perpendicularly to the layer planes—a ferrimagnetic reference layer and a ferri- or ferromagnetic free layer, wherein the coercive field strength of the reference layer—is larger than that of the free layer and both layers are separated by an intermediate layer is set up in such a manner that an exchange bias is set. The condition for setting an exchange anisotropy is (KRS·dRS)/J(dZS)>1. In this case, KRS is the anisotropy of the reference layer and dRS is the thickness thereof. J(dZS) designates the coupling constant, which is a function of the layer thickness of the intermediate layer dZS. The exchange bias field HEB has a size of a few hundred to a few ten thousand A/m (a few ten to thousand Oe). The size of the field HEB is set—in addition to the already mentioned coupling constant J(dZS)—by means of the magnetic permeability of the vacuum μ0 and the further parameters magnetisation of the free layer MFS, and the thickness dFS thereof according to HEB˜J(dZS)/μ0·MFS·dFS. If the exchange bias field HEB is set to a value in the above-mentioned range, a change in direction of the magnetic orientation of the free layer takes place at room temperature in the case of a corresponding external field. The exchange bias stabilises the preferred orientation of the free layer.

The reference layer and the free layer are formed from materials, which have a single-domain state with respect to the magnetisation and also a perpendicular anisotropy with respect to the layer planes. This is the prerequisite for the exclusion of a training effect. The perpendicular alignment of the magnetisation additionally contributes to the thermal stability of the spin valve. Whereby the reference layer, as already mentioned, is formed from a ferrimagnetic material, which fulfils the preceding conditions, and the free layer can be formed from a ferro- or ferrimagnetic material, which fulfils the preceding conditions. If the free layer is formed from a ferrimagnetic material, this has an advantageous effect on the achievable memory speed. Storing in the case of a ferrimagnetic free layer can also take place with support from a laser within picoseconds, compared to the nanoseconds required in conventional elements.

The reference layer is formed from an alloy, which consists at least of a rare earth element and a transition metal.

A memory unit using spin valves, as are characterised as outlined, is stabilised in such a manner by the coercive field strength of the reference layer and by the exchange bias field that it is stable at room temperature for a few days to a few years, depending on the choice of materials and the parameters set. Using a field of a few hundred to a few ten thousand A/m (a few tens to a few hundred Oe), it is possible to reset the entire stored information, without a training effect being set. With respect to the temporal stability for the simultaneous possibility of a read and write access and a possible reset, a memory unit of this type is to be termed semi-volatile.

The temporal stability of the information depends on the size of the coercive field strength of the reference layer. The size thereof is set via the composition of the reference layer and is more than 0.8 kA/m (100 Oe). The larger the coercive field strength is, the better thermal fluctuations in the system are captured.

The stabilisation of the spin valves also has an effect on the possible scaling thereof. Spin valves according to the invention can be realised in sizes from 30×30 nm2. This allows very high memory densities.

In one embodiment, the reference layer is formed from DyzCo(1-z), where z is between 5 and 35 at.%. DyzCo(1-z) is ferrimagnetic and characterised by a single-domain magnetisation and a large uniaxial anisotropy K, which is represented by a very large orbital moment. The direction of the magnetisation in the spin valve of DyzCo(1-z) is orientated perpendicularly to the layer planes.

In a different embodiment, the free layer is formed from FezGd(1-z), where z is between 5 and 95 at.%. FezGd(1-z) is ferrimagnetic and characterised in that the magnetisation or coercive field strength thereof can be set by variation of z in a range from 0.8 to 800 kA/m (10 to 10,000 Oe). This material also has a single-domain magnetisation. The direction of the magnetisation of FezGd(1-z) in the spin valve is orientated perpendicularly to the layer planes. The free layer can however also be formed from an alloy of Co—Pd or Co—Pt or from Co—Pd or Co—Pt multilayers.

In a further embodiment, the intermediate layer is formed from one of the elements, vanadium, chromium, copper, niobium, molybdenum, ruthenium, rhodium, tantalum, tungsten, rhenium or iridium for use as a GMR element.

In a different embodiment, the intermediate layer is formed from one of the oxides MgO, Al2O3, BaTiO3 or BaFeO3 for use as a TMR element.

The following embodiments relate to the thicknesses of the individual layers. Thus, this is between 0.1 and 1000 nm for the reference layer and the free layer and between 0.1 nm and 2 nm for the intermediate layer.

Depending on the choice of materials for the intermediate layer, conductive or insulating, the described spin valve can be used as a TMR unit or as a magnetoresistive unit.

The invention shall hereinafter be explained in more detail in the following exemplary embodiment on the basis of drawings.

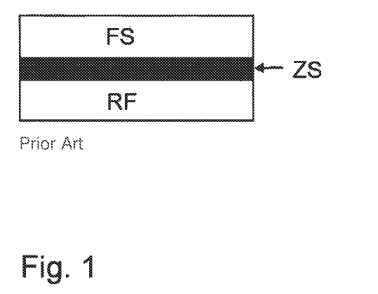

The layer structure of a spin valve shown in FIG. 1 corresponds to the prior art. It comprises the reference layer RS, the free layer FS and the intermediate layer ZS. According to an exemplary embodiment of the invention, the reference layer RS is formed from DyCo5 and has a thickness of 25 nm. The free layer FS is formed from Fe76Gd24 and has a thickness of 50 nm. The intermediate layer ZS is formed from tantalum and has a thickness of 0.5 nm. The reference layer and the free layer are arranged in such a manner that the preferred orientation of the magnetisation thereof is perpendicular to the layer planes.

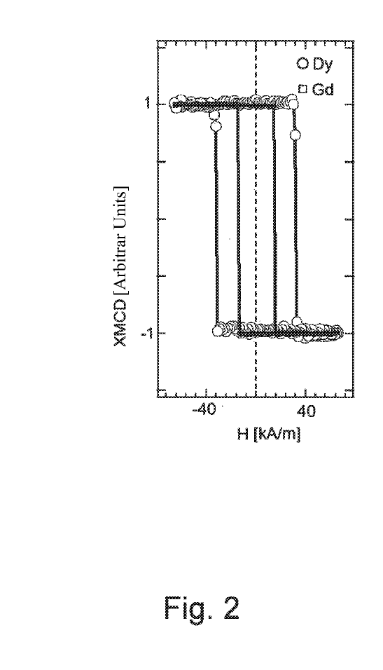

The hystereses shown in FIG. 2 are those of dysprosium (Dy) and gadolinium (Gd) in the described spin valve. The hysteresis curves were determined by means of a study of the x-ray magnetic circular dichroism (XMCD). The different absorption of left and right circularly polarised x-ray light is measured in this method. The circularly polarised x-ray light interacts with the magnetic moments in the sample, here the spin valve. If the magnetic moments show a preferred orientation, then the absorption of the circularly polarised x-ray light depends on the angle between the magnetic orientation and the polarisation of the x-ray light. The difference of the absorption spectra of left and right polarised light is directly proportional to the magnetisation. It is measured at the K, L or M edges. If an external magnetic field is applied, then one can trace the change in the magnetisation in the sample using the change in the magnetic field. All XMCD measurements, which are presented here, were carried out in transmission geometry at BESSY II (Berliner Elektronen Speicherring des Helmholtz-Zentrum-Berlin) using the ALICE diffractometer at the PM3 experimental facility and the high field chamber at the UE46-PGM1 experimental facility. The difference in the absorption spectra measured with left and right circularly polarised light at the M5 edges of dysprosium and gadolinium is given on the abscissa in arbitrary units of XMCD. The applied external field H in amperes per metre [A/m] is plotted on the ordinate. Both hystereses are characterised by an approximately square shape. This is characteristic of the single-domain state with perpendicular magnetisation both of the DyCo5 and the Fe76Gd24 in the spin valve according to the invention described in FIG. 1, which is a prerequisite for the exclusion of a training effect. In addition, it can be seen that the coercive field strength of Fe76Gd24 at 13.6 kA/m (170 Oe) is smaller than that of DyCo5 at 28 kA/m (350 Oe). The coercive field strength of Fe76Gd24 is higher here under exchange anisotropy than in the decoupled state, where it is 4.8 kA/m (60 Oe).

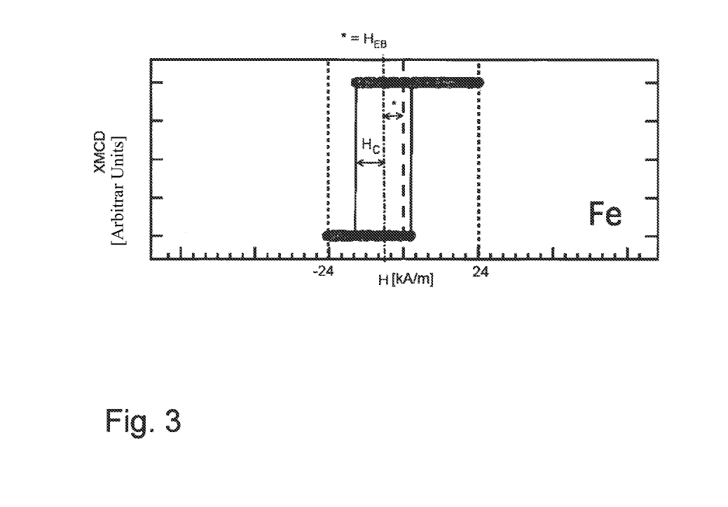

The hysteresis of iron (Fe) shown in FIG. 3 in the described spin valve was determined according to the description of FIG. 2 using XMCD. The difference in the absorption spectra measured with left and right circularly polarised light at the L3 edge of iron Fe is given on the abscissa in arbitrary units XMCD. The applied external field H in amperes per metre A/m is plotted on the ordinate. The spin valve was saturated in a magnetic field of 240 kA/m (3 kOe) before the measurement. Here also, the hysteresis is characterised by an approximately square shape, which again proves the single-domain state with perpendicular magnetisation of Fe76Gd24 in the arrangement according to the invention, which is a prerequisite for the exclusion of a training effect. The hysteresis does not run symmetrically with the applied field, but rather is shifted with respect to the abscissa. This is a sign for the presence of an exchange anisotropy. The exchange bias field HEB is 6.4 kA/m (80 Oe) and the coercive field strength Hc of the iron is 8.96 kA/m (112 Oe).

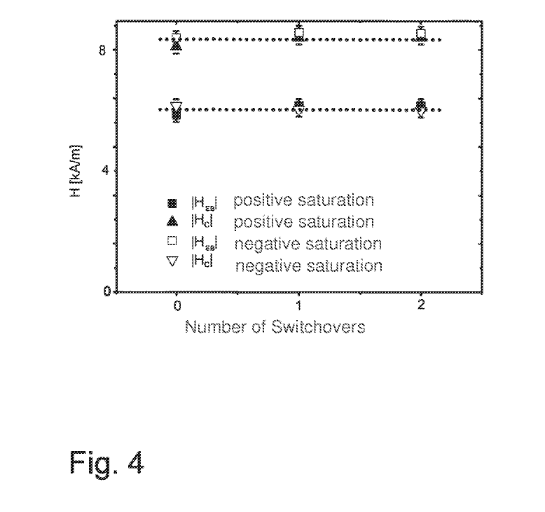

In FIG. 4, the coercive field strengths Hc and the amounts for the exchange bias field strengths HEB in amperes per metre [A/m] are plotted on the abscissa. The number of switchovers of the orientation of the magnetisation of the free layer by fields of ±24 kA/m (300 Oe) is shown on the ordinate. The entire arrangement was in this case aligned in a field of 240 kA/m (3 kOe), designated as positive here, then HEB and Hc were determined and this was repeated after two switchovers of the free layer in each case. Subsequently, the entire arrangement was aligned in the opposite direction in a field of 240 kA/m (3 kOe), designated as negative here, then HEB and Hc were determined and the same was repeated after two switchovers in each case. HEB and Hc remain constant here, which in turn shows that there is no training effect present.

The described spin valve with the listed features can consequently be read and written at room temperature and field strengths <16 kA/m (200 Oe). A reset to a defined orientation is likewise possible at room temperature for field strengths >28 kA/m (350 Oe). The temporal stability of the information depends on the size of the coercive field strength of the DyCo5. As the intermediate layer is formed from tantalum, the spin valve can be used as a magnetoresistive unit.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A spin valve comprising:
two layers magnetised perpendicularly to a layer plane and an intermediate layer disposed between the magnetic layers, wherein one layer is reference layer for predetermining a preferred orientation of a direction of the magnetisation and is formed from a ferrimagnetic material and has a higher coercive field strength than the other free layer, which is formed from a ferromagnetic or ferrimagnetic material, wherein:
the intermediate layer is one of electrically conductive or non-conductive,
the reference layer and the free layer have a single-domain magnetisation,
the reference layer is at least formed from an alloy comprising a rare earth element and a transition metal,
the coercive field strength of the reference layer is settable via the composition thereof and is more than 0.8 kA/m,
an anisotropy (KRS) and layer thickness (dRS) of the reference layer and a coupling constant (J), which is a function of a layer thickness (dZS) of the intermediate layer fulfill a condition for forming an exchange bias with (KRS·dRS)/J(dZS)>1, and the exchange bias field has values between 0.8 and 80 kA/m.

2. The spin valve according to claim wherein the reference layer is formed from DyzCo(1-z), wherein z is between 5 and 35%.

3. The spin valve according to claim 1, wherein the free layer is formed from FezGd(1-z), wherein z is between 0.05 and 0.95.

4. The spin valve according to claim 1, wherein the free layer is formed from an alloy of at least one of Co—Pd or Co—Pt.

5. The spin valve according to claim 1, wherein the intermediate layer is formed from an element selected from the group consisting of vanadium, chromium, copper, niobium, molybdenum, ruthenium, rhodium, tantalum, tungsten, rhenium and iridium.

6. The spin valve according to claim 1, wherein the intermediate layer is formed from an oxide selected from the group consisting of MgO, Al2O3, BaTiO3 or and BaFeO3.

7. The spin valve according to claim 1, wherein the thickness of the reference layer is between 0.1 and 1,000 nm.

8. The spin valve according to claim 1, wherein the thickness of the free layer is between 0.1 to and 1,000 nm.

9. The spin valve according to claim 1, wherein the thickness of the intermediate layer is between 0.1 nm and 2 nm.

10. The spin valve according to claim 1, wherein the reference layer comprises DyCo5 and has a thickness of 25 nm, the intermediate layer comprises tantalum and has a thickness of 0.5 nm and the free layer comprises Fe76Gd24 and has a thickness of 50 nm.

11. A multiplicity of spin valves according to claim 1 configured for use as magnetoresistive RAMs wherein each spin valve has a semi-volatile behavior of a temporal stability at room temperature of between a few days and a few years with the simultaneous possibility of a read and write access and by a reset of the stored information via a field of between a few hundred and a few ten thousand A/m without setting a training effect.

12. The spin valve according to claim 1, wherein the free layer is formed from an alloy of at least one of Co—Pt multilayers or Co—Pd multilayers.
